(19) United States
(12) Patent Application Publication
(10) Pub. No.: US 2011/0051333 A1
(43) Pub. Date: Mar. 3, 2011

(54) Device for fastening and electrically wiring a plurality of electrical units, particularly in a switching cabinet

(75) Inventor: Jürgen Lang, Ludwigsburg (DE)

(73) Assignee: FRIEDRICH LUTZE GMBH & CO. KG

(21) Appl. No.: 12/805,741

(22) Filed: Aug. 18, 2010

(30) Foreign Application Priority Data
Aug. 27, 2009 (DE) 10 2009 039 951.8

(51) Int. Cl. H05K 7/00

(52) U.S. Cl. 361/679.01

(57) ABSTRACT

Device for fastening and electrically wiring a plurality of electrical units, particularly in a switching cabinet.

The invention relates to a device (10) for fastening and electrically wiring a plurality of electrical units, particularly in a switching cabinet (1), the device (10) having a mounting element (14) with one mounting side (16) on which the electrical units can be arranged and fastened, characterized in that the mounting element (14) borders a wiring space (18) for wiring of the electrical units, that the mounting element (14) has at least one other mounting side (20) on which electrical units can be arranged and fastened, and that the wiring space (18) is accessible for wiring of electrical units fastened on at least two mounting sides (16, 20) of the mounting element (14).

The invention relates to a device for fastening and electrically wiring a plurality of electrical units, particularly in a switching cabinet.

Electrical units for industrial control engineering are often located in switching cabinets or switchboxes. EP 0 902 513 A2 discloses a device for fastening and electrically wiring a plurality of these electrical units, particularly in a switching cabinet, in which the electrical units can be located and fastened on a mounting element on one mounting side of a mounting strip. Wiring of the electrical units takes place in a wiring space located next to the mounting element.

In some applications, it is preferable or necessary to classify the electrical units, for example, as power elements and sensor elements. This increases wiring effort, resulting in corresponding costs for material and labor. Moreover, the packing density of the electrical units is in part high, such that large-volume and large-area switching cabinets are necessary.

The object of this invention is to devise a device for fastening and electrical wiring of a plurality of electrical units, particularly in a switching cabinet, which overcomes the disadvantages of the prior art. In one embodiment, the possible applications of the device are designed to be enhanced, especially the possibilities of wiring are designed to be improved with simultaneous minimization of effort, and/or the packing density of the electrical units is designed to be increased.

The invention is achieved by the device defined in claim 1. Special embodiments of the invention are defined in the dependent claims.

In one embodiment, the mounting element borders the wiring space for wiring of the electrical units. The mounting element can border the wiring space at least on one side, preferably two or three sides. The mounting element can border the wiring space on three of four sides, on the fourth side there being an opening for routing the wiring into the wiring space and/or for routing the wiring out of the wiring space. The opening can extend over the entire longitudinal direction of the mounting element.

In one embodiment, the mounting element has at least one further mounting side on which electrical units can be arranged and fastened. This makes it possible to arrange electrical units on at least two, preferably on exactly two sides of the mounting element. As a result the packing density of the electrical units can be increased. The wiring space is accessible to wiring of electrical units fastened to at least two mounting sides of a mounting element. As a result, electrical units located on different mounting sides can be wired by way of electrical lines routed in the wiring space. This reduces wiring effort. The electrical units can moreover be grouped by the arrangement of electrical units on several mounting sides of the mounting element, for example, with the formation of groups of power-switching units, control units, safety units, sensor units, and/or converter units.

The mounting elements are inherently stable as a result of their geometrical shape and/or of the material, even when taking into account the electrical units to be fastened to the mounting element. As a result, the use of mounting plates can be dispensed with, on which in the prior art either electrical units with a high mass or the mounting elements themselves must be fastened. The mounting elements can be made of metal, especially a lightweight metal, for example, aluminum. The mounting element can be formed in one piece from a profile, or can be assembled from several profiles.

The mounting element can be fastened on a support means, for example, directly in the switching cabinet or on support rails which run preferably at a right angle to the mounting elements. In some applications it is especially advantageous if the mounting elements have a vertically aligned longitudinal axis because then the conductors can be routed in and out in the wiring space in the vertical direction. In this case the mounting element can be fixed on the support rails of the support means, which rails run obliquely to the mounting element and especially horizontally.

In one embodiment, the mounting element is made on at least two mounting sides such that fastening of the electrical units can take place in a harmonious manner, for example, by way of standardized fastening rails, for example, C-rails or top-hat rails. Alternatively, the mounting element can also be made differently on at least two mounting sides; for example, there can be different mounting rails, such as a C-rail on one mounting side and a top-hat rail on the other mounting side.

In one embodiment, electrical units can be arranged and fastened on at least two mounting sides which are opposite one another relative to the longitudinal direction of the mounting element. For example, the electrical units can be arranged on the front mounting side and on the rear mounting side of the mounting element so that, for example, separation of the power and control part, separation of low and high voltage, and/or separation of electrical units with low and with high power loss can take place by this grouping. In this way cooling of the electrical units can be improved; this takes place, for example, in a switching cabinet essentially by convection within the switching cabinet and by radiation via the surfaces of the switching cabinet. Generally, on the back of the mounting element a lower air temperature prevails than on the front, so that the electrical units also can be arranged and fastened according to their individually required ambient temperature.

In one embodiment, the wiring space is located between two mounting sides of the mounting element. The wiring space is accessible from the outside via a side wall which is located in between. This yields short connection paths for the wiring of the electrical units located on the two mounting sides.

In one embodiment, the mounting element on the outer surface, which is aligned obliquely and especially transversely to the mounting side, has an opening for access to the wiring space. The mounting element can be made essentially C-shaped in cross section. On one edge of the opening, which extends preferably along the longitudinal axis of the mounting element, there can be a wiring fan. Specifically, a wiring fan can be inserted into an opening made for this purpose from the edge. The wiring fan and/or the opening itself can be at least partially closed with a closure element.

In one embodiment, the mounting element forms a hollow profile whose outer sides form the mounting sides and whose cavity forms the wiring space. The cavity can be tetragonal in cross section, especially more or less rectangular or square. On at least one side the hollow profile has openings for passage of wiring lines.

In one embodiment, the mounting element on all mounting sides has an attachment rail with which the electrical units can be fastened. The attachment rail can extend over the entire length of the mounting element. The attachment rail can be made, for example, as a top-hat rail or C-rail.

In one embodiment, the attachment rail is formed integrally by the mounting element. In particular, the attachment rail can be formed integrally from a mounting strip which forms the mounting side. The mounting strip can be formed by an elongated and essentially flat profile.

In one embodiment, the mounting element has a mounting strip which forms the mounting side and which borders the wiring space. The mounting element can have at least two mounting strips which are connected to one another by means of a connecting element.

In one embodiment, the wiring space can be divided into at least two component spaces by means of a separating element which is connected to the mounting strip. The separating element can on the one hand divide the wiring space and on the other join the mounting strips to one another. Preferably, the wiring space is separated into two component spaces of the same size. The component spaces can be essentially identical with respect to their cross-sectional outline and/or cross-sectional area, particularly mirror-image to the separating element. The separating element can be formed by a preferably flat profile whose longitudinal direction coincides with the longitudinal direction of the mounting element. The width of the separating element determines the height of the wiring space between two mounting strips. Mounting elements with wiring spaces of different size can be easily formed by making available several separating elements with different width.

In one embodiment, the mounting strip has a groove which is open toward the mounting side for holding fasteners, for example, screws, for joining the mounting strip to the separating element. In this way, the mounting strip can be easily and, preferably, also detachably joined to the separating element.

In one embodiment, the separating element, at the connecting site to the mounting strip, has a slot which is grooved in the longitudinal direction of the separating element for screwing in a fastener. The grooving can be easily produced in the production of the profile for the separating element without requiring further machining steps; in particular, it is not necessary to provide threaded holes in the separating element. Alternatively or in addition, the separating element at the connecting site to the mounting strip has a slide nut channel. The separating element can also have a grooved slot at the first connecting site to the first mounting strip and can have a slide nut channel at a second connecting site to a second mounting strip.

In one embodiment, the separating element has a slide nut channel to which other elements within the wiring space can be fastened. For example, a line-routing means such as, for example, a cable catch can be fastened within the wiring space. The slide nut channel can be formed integrally by the separating element.

In one embodiment, the separating element has openings for passage of electrical lines from one component space into the adjacent component space of the wiring space. Alternatively or in addition, the separating element can also be interrupted so that within the mounting element there are two or more separating elements with a distance in the longitudinal direction to one another, and the distance forms an opening for passage of the wiring.

In one embodiment, the mounting strip has at least one slide nut channel; preferably the mounting strip to both sides of the fastening rail has at least one slide nut channel. Either alternatively or additionally to the mounting rail, electrical units can be fixed on the mounting element by means of this slide nut channel, or the mounting element itself can be connected to the support means using the slide nut channel. For this purpose, for example, mounting clips can engage the slide nut channel with one clip section, and the mounting clips can be fixed with a fixing section on the support means, for example, can be screwed to the support means. On the clip section the mounting clips can have an opening which is engaged by a fastener, for example, can have a threaded hole by means of which the clip section can be secured in the slide nut channel.

In one embodiment, at least two mounting sides of the mounting element are formed by mounting strips made as identical parts. Thus, in spite of the mounting element being composed of several parts, economical production is ensured since only a single tool is necessary for producing the mounting strips. In one embodiment, mounting strips with different width in the form of a modular system can be provided, and, for producing the mounting element, mounting strips of different width can also be combined with one another. Alternatively or in addition, the separating elements can also have a different width so that a plurality of dimensions for the wiring space is possible, and the mounting element can be assembled in the form of a module from available mounting strips and separating elements, adapted to the respective application.

Other advantages, features, and details of the invention will become apparent from the dependent claims and the following description, in which, with reference to the drawings, several exemplary embodiments are described in detail. The features mentioned in the claims and the description can be essential for the invention individually for themselves or in any combination.

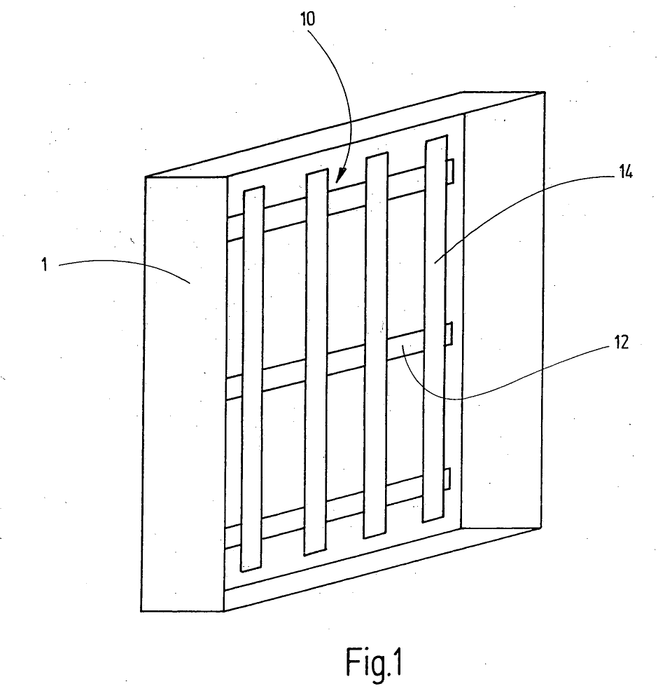

FIG. 1 shows a perspective view of a switchbox or switching cabinet,

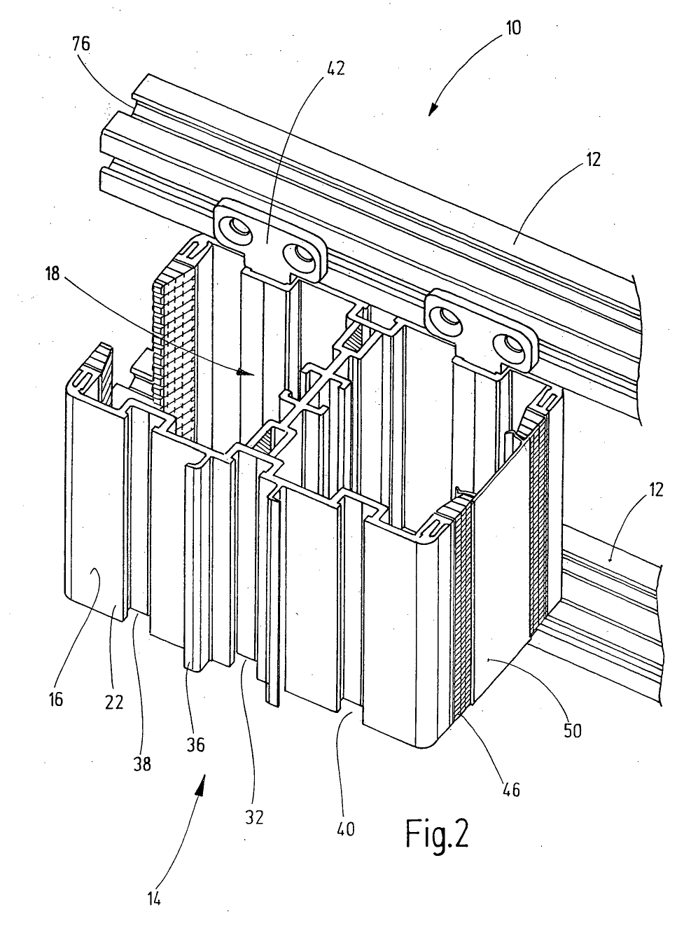

FIG. 2 shows a perspective view of a cutaway view of one exemplary embodiment of the device according to the invention,

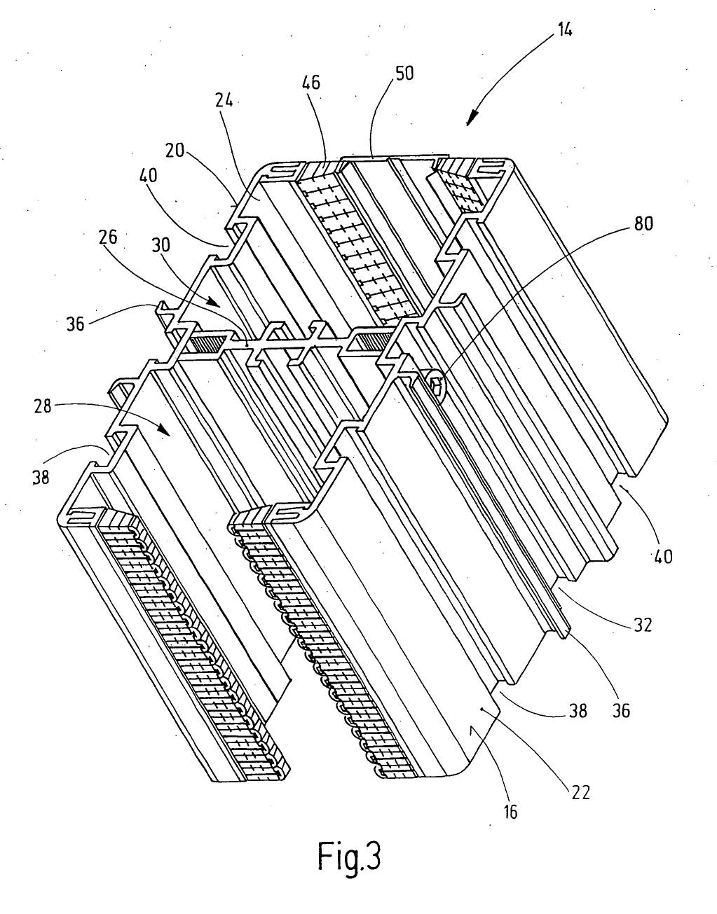

FIG. 3. shows a perspective view of a section of the mounting element,

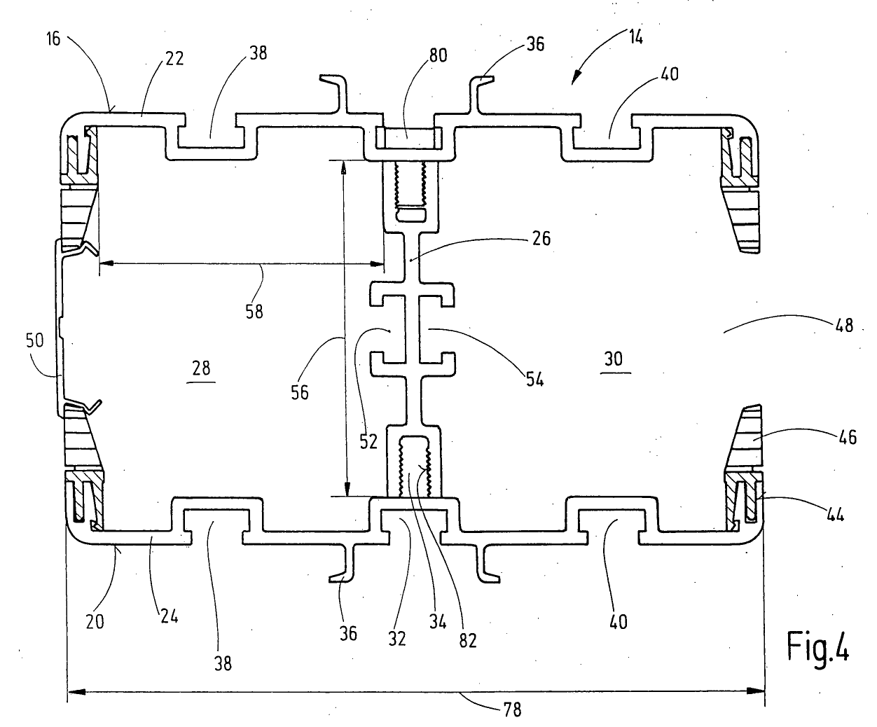

FIG. 4 shows a section through the mounting element transversely to its longitudinal axis,

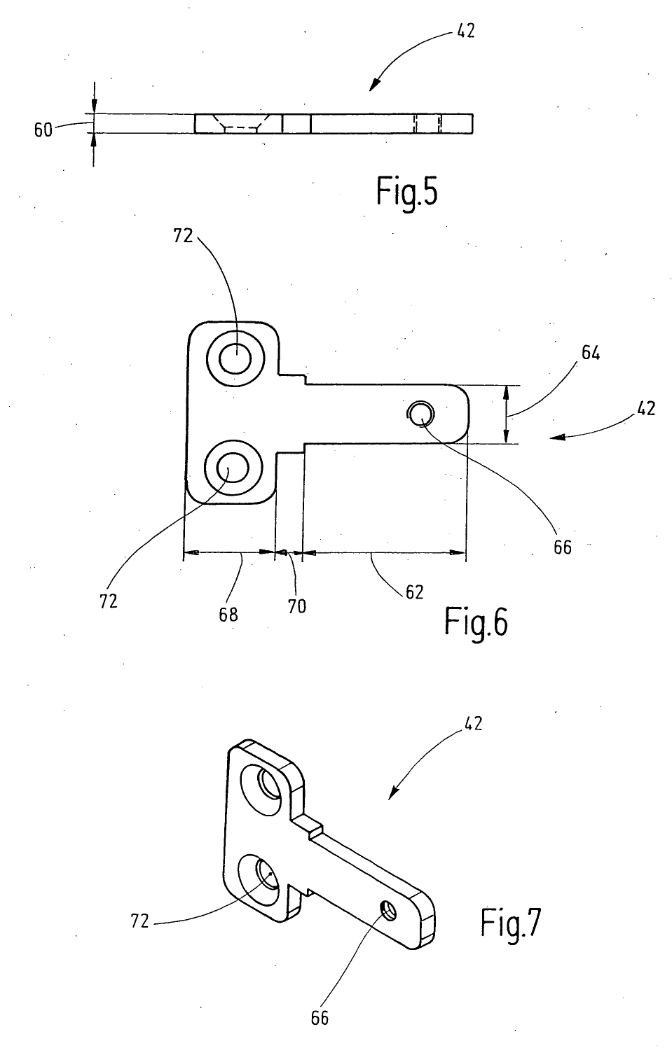

FIG. 5 shows a side view of a mounting clip,

FIG. 6 shows a top view of the mounting clip, and

FIG. 7 shows a perspective view of the mounting clip.

FIG. 1 shows a perspective view of a switchbox or a switching cabinet 1 as is used for mounting of electrical control units, for example, in industrial production engineering. In the switching cabinet 1, there is a device 10 for fastening and electrically wiring a plurality of electrical units, in the illustrated embodiment the device 10 having horizontally running support rails 12 of a support means and vertically running mounting elements 14 connected thereto. Alternatively, the support rails 12 can also run vertically and the mounting elements 14 horizontally, or some of the mounting elements 14 run horizontally and some of the mounting elements 14 run vertically.

FIG. 2 shows a perspective view of a cutaway view of one exemplary embodiment of the device 10 according to the invention. The horizontally running support rails 12 are formed by an aluminum profile which on four outer sides has one slide nut groove 76 each for fastening the mounting element 14. The mounting element 14 has one mounting side 16 on which electrical units which are not shown for reasons of clarity can be arranged and fastened. The mounting element 14 borders the wiring space 18 for wiring of electrical units. The wiring space 18 in the illustrated exemplary embodiment has two parts, the two component spaces 28, 30 (FIG. 4) of the wiring space 18 being accessible for wiring both of electrical units fastened to the mounting side 16 and also being accessible for wiring of electrical units fastened to the other mounting side 20.

The mounting element 14 has another mounting side 20 which is opposite the mounting side 16 (FIG. 4) and on which electrical units can likewise be arranged and fastened. In the exemplary embodiment, one mounting side 16 can be outfitted from the front of the switching cabinet 1, while the other mounting side 20 can be outfitted from the back. In one switching cabinet 1, rear side outfitting can be, for example, simplified by the switching cabinet 1 also having a door on the back. Alternatively or in addition, the mounting elements 14 can also be located on a pivoting frame which can be pivoted to the outside by way of a pivot bearing which, for example, has pivot pins. The other mounting side 20 is located closer to the support rails 12 than to the mounting side 16. On the other mounting side 20 there can be, for example, electrical units which have a large mass. Due to the smaller distance of the other mounting side 20 from the support rails 12, the torque applied to the support rail 12 by the force of gravity acting on the electrical units is smaller than in the arrangement of the electrical units on the mounting side 16.

FIG. 3 shows a perspective view of one section of the mounting element 14, and FIG. 4 shows a section through the mounting element transversely to its longitudinal axis. The mounting element 14 is formed from two mounting strips 22, 24 which run parallel to one another and spaced apart from one another, and a separating element 26 located in between. The separating element 26 separates the wiring space 18 into two component spaces 28, 30. The separating element 26 is located in the center relative to the width 78 of the mounting strips 22, 24. The separating element 26 extends like the mounting strips 22, 24 in the longitudinal direction of the mounting element 14 perpendicular to the plane of the drawing in FIG. 4. The two component spaces 28, 30 are essentially identical and a mirror-image to the mirror plane determined by the separating element 26.

The mounting strips 22, 24 are made as identical parts. In the middle, with reference to their width 78, the mounting strips 22, 24 have a first slide nut groove 32 which holds a section of a fastener 80, for example, the head of a fastening screw, by means of which the mounting strips 22, 24 are connected to the separating element 26. The separating element 26 for this purpose at the connecting site to the mounting strip 22, 24 has a groove 34 which runs in the longitudinal direction of the separating element with grooves 82 for screwing in the fastener 80.

The mounting strips 22, 24, centrally with reference to the width 78, likewise have an attachment rail 36 which is formed integrally by the mounting strips 22, 24, in this exemplary embodiment a top-hat rail on which the electrical units can be seated. On both sides of the attachment rail 36, the mounting strips 22, 24 each have a second and a third slide nut groove 38, 40. As is apparent from FIG. 2, using this second and/or third slide nut groove 38, 40, the mounting element 14 can be connected to the support rail 12, in the illustrated embodiment by means of a mounting clip 42 which is detailed below. The second and third slide nut grooves 38, 40 are spaced equally to the first slide nut groove 32. The two mounting strips 22, 24 are symmetrical to the center plane of the mounting element 14.

On the two side ends, the mounting strips 22, 24 are angled by 90° and form openings 44 for insertion of a wiring fan 46 for orderly routing of the electrical lines into or out of the wiring space 18 or the two component spaces 28, 30. Between the wiring fans 46 opposite one another, the mounting element 14 has an opening 48 which can be closed with an insertable closure element 50 which can be locked to the fans 46. As is apparent especially from FIG. 4, the two component spaces 28, 30 of the wiring space 18 are accessible, for example, via the opening 48 both for electrical units which are located on the mounting side 16, especially the fastening rail 36, and also for electrical units located on the other mounting side 20.

The separating element 26 on each side has one slide nut channel 52, 54 each with which, for example, a cable guide can be fastened in the component space 28, 30 of the wiring space 18.

In the illustrated exemplary embodiment, the width 56 of the separating element 26 which determines the inside height of the wiring space 18 and of the component spaces 28, 30 is between 30 and 100 mm, especially between 40 and 80 mm, and preferably between 60 and 70 mm. The width 58 of the component spaces 28, 30 is between 20 and 150 mm, especially between 40 and 100 mm, and preferably between 50 and 70 mm. The width 78 of the mounting strips 22, 24 in the exemplary embodiment is between 80 and 200 mm, especially between 100 and 180 mm, and preferably between 120 and 160 mm. The cross-sectional area of the wiring space 18 and of the component spaces 28, 30 can be adapted to the respective application by varying the width 56 of the separating element 26 and/or the width of the mounting strips 22, 24.

FIG. 5 shows a side view of a mounting clip 42, by means of which the mounting element 14 can be connected to the support rail 12. FIG. 6 shows a top view of the mounting clip 42, and FIG. 7 shows a perspective view of the mounting clip 42.

The mounting clip 42 is preferably stamped out of a flat material and has a constant thickness 60 of between 2 and 6 mm typical in the exemplary embodiment, especially between 3 and 5 mm, and preferably roughly 4 mm. The mounting clip 42 has a clip-shaped section 62 which has an essentially constant width 64 over a length of more than 30 mm, and which can be inserted into the second and/or third slide nut groove 38, 40 of the mounting strip 22, 24. In a section which has been displaced off-center relative to the longitudinal direction and especially toward the free end, the clip-shaped section 62 has a threaded hole 66 into which a threaded pin can be screwed, and in this way the mounting clip 42 can be fixed in the slide nut groove 38, 40.

On its end facing the fastening section 68, the mounting clip 42 has a section 70 which is widened relative to the clip-shaped section 62 and which forms a stop when the mounting clip 42 is inserted into the slide nut groove 38, 40. The transition from the clip-shaped section 62 to the widened section 70 is preferably abrupt and without a radius, so that there is a defined stop when the mounting clip 42 is inserted into the slide nut groove 38, 40. In the region of the fastening section 68, there are two openings 72 by means of which the mounting clip 42 can be connected to the support rail 12 using flat head bolts, especially by screwing to a nut located in the slide nut groove 76 of the support rail 12.

The length of the clip-shaped section 62 can be matched to the respective application, especially to the mass of the electrical units which are to be arranged on the mounting element 14, as well as the thickness 60 of the mounting clip 42 and/or the width 74 of the fastening section 68. Therefore, a wide range of applications of the device 10 according to the invention can be accommodated with respect to the mounting clip in the form of a modular system with comparatively few elements.

1. A device (10) for fastening and electrically wiring a plurality of electrical units, particularly in a switching cabinet (1), the device (10) having a mounting element (14) with one mounting side (16) on which the electrical units can be arranged and fastened, characterized in that the mounting element (14) borders a wiring space (18) for wiring of the electrical units, that the mounting element (14) has at least one other mounting side (20) on which electrical units can be arranged and fastened, and that the wiring space (18) is accessible for wiring of electrical units fastened on at least two mounting sides (16, 20) of the mounting element (14).

2. The device (10) according to claim 1, characterized in that electrical units can be arranged and fastened on at least two mounting sides (16, 20) which are opposite one another relative to the longitudinal direction of the mounting element (14).

3. The device (10) according to claim 1, characterized in that the wiring space (18) is located between two mounting sides (16, 20) of the mounting element (14).

4. The device (10) according to claim 1, characterized in that the mounting element (14) has an opening (48) for access to the wiring space (18) on the outer surface which is aligned obliquely and especially transversely to the mounting side (16, 20).

5. The device (10) according to claim 1, characterized in that the mounting element (14) forms a hollow profile whose outer sides form the mounting sides (16, 20) and whose cavity forms the wiring space (18).

6. The device (10) according to claim 1, characterized in that the mounting element (14) on all mounting sides (16, 20) has an attachment rail (36) with which the electrical units can be fastened.

7. The device (10) according to claim 6, characterized in that the attachment rail (36) is formed integrally by the mounting element (14), especially is formed integrally by the mounting strip (22, 24) which forms the mounting side (16, 20).

8. The device (10) according to claim 1, characterized in that the mounting element (14) has a mounting strip (22, 24) which forms the mounting side (16, 20) and which borders the wiring space (18).

9. The device (10) according to claim 8, characterized in that the wiring space (18) is divided into at least two component spaces (28, 30) by means of a separating element (26) which can be connected to the mounting strip (22, 24).

10. The device according to claim 8, characterized in that the mounting strip (22, 24) has a slot (32) which is open to the mounting side (16, 20) for accommodating fasteners (80) for connecting the mounting strip (22, 24) to the separating element (26).

11. The device according to claim 8, characterized in that the separating element (26) is formed by a preferably flat profile.

12. The device according to claim 8, characterized in that the separating element (26) at the connection site to the mounting strip (22, 24) has a slot (34) which has grooves (82) and which runs in the longitudinal direction of the separating element (26) for screwing in a fastener (80).

13. The device (10) according to claim 8, characterized in that the separating element (26) has a slide nut channel (52, 54).

14. The device (10) according to claim 8, characterized in that the separating element (26) has openings for passage of wiring from one component space (28, 30) into the adjacent component space (28, 30).

15. The device (10) according to claim 1, characterized in that the mounting strip (22, 24) has at least one slide nut channel (38, 40), preferably has one slide nut channel (38, 40) each on both sides of the fastening rail (42).

16. The device (10) according to claim 1, characterized in that at least two mounting sides (16, 20) of the mounting element (14) are formed by mounting strips (22, 24) made as identical parts.
